(19) United States
(12) Patent Application Publication
(10) Pub. No.: US 2022/0272839 A1
(43) Pub. Date: Aug. 25, 2022

(54) FLEXIBLE PRINTED WIRING BOARD, BATTERY WIRING MODULE, AND METHOD OF MANUFACTURING FLEXIBLE PRINTED WIRING BOARD

(71) Applicants: SUMITOMO ELECTRIC PRINTED CIRCUITS, INC., Koka-shi, Shiga (JP); SUMITOMO ELECTRIC INDUSTRIES, LTD., Osaka-shi, Osaka (JP); SUMITOMO WIRING SYSTEMS, LTD., Yokkaichi, Mie (JP); AUTONETWORKS TECHNOLOGIES, LTD., Yokkaichi, Mie (JP)

(72) Inventors: Yoshifumi UCHITA, Koka-shi (JP); Shinichi TAKASE, Yokkaichi (JP); Hideo TAKAHASHI, Yokkaichi (JP)

(73) Assignees: SUMITOMO ELECTRIC PRINTED CIRCUITS, INC., Koka-shi, Shiga (JP); SUMITOMO ELECTRIC INDUSTRIES, LTD., Osaka-shi, Osaka (JP); SUMITOMO WIRING SYSTEMS, LTD., Yokkaichi, Mie (JP); AUTONETWORKS TECHNOLOGIES, LTD., Yokkaichi, Mie (JP)

(21) Appl. No.: 17/624,630

(22) PCT Filed: Jul. 9, 2020
(86) PCT No.: PCT/JP2020/026938

§ 371 Date: Jan. 4, 2022

(30) Foreign Application Priority Data
Jul. 10, 2019 (JP) 2019-128681

(51) Int. Cl. H05K 1/11; H05K 1/02; H05K 3/40; H01M 50/519

(52) U.S. Cl. CPC H05K 1/11; H05K 1/0277; H05K 3/40; H01M 50/519; H05K 2201/10037; H01M 2220/20

(57) ABSTRACT

A flexible printed wiring board according to an aspect includes an insulating base film and a conductive pattern stacked on one surface side of the base film. The flexible printed wiring board further includes one or more square-shaped connecting terminals stacked over the conductive pattern with solder in between on one edge side of the conductive pattern. The connecting terminal is made of metal and includes a bent portion with both ends bent opposite to the base film. The connecting terminal includes a plated layer on an outer surface side of the bent portion.

### TECHNICAL FIELD

The present disclosure relates to a flexible printed wiring board, a battery wiring module, and a method of manufacturing a flexible printed wiring board. The present application claims a priority based on Japanese Patent Application No. 2019-128681 filed on Jul. 10, 2019, the entire contents of which are incorporated herein by reference.

### BACKGROUND ART

As recent electronic devices have a smaller size and a lighter weight, electronic parts of an electronic device, such as planar coil elements, are mounted on a flexible printed wiring board and have a smaller size.

This flexible printed wiring board has, on one edge side, a metallic connecting terminal for connection with any other printed wiring board, electronic device, or the like (e.g., see Japanese Patent Laying-Open No. 2011-159880). This connecting terminal has a square plate shape, and is connected to a conductive pattern of the flexible printed wiring board with a conductive layer made of solder or the like in between.

In order to improve adhesion between the metallic connecting terminal and the conductive pattern to prevent or reduce the occurrence of cracks of solder or the like, for example, a solder fillet may be formed at the lateral lower edge of the connecting terminal. Plating of an end surface of the metallic connecting terminal is required for stable formation of the solder fillet.

### CITATION LIST

### Patent Literature

PTL 1: Japanese Patent Laying-Open No. 2011-159880

### SUMMARY OF INVENTION

A flexible printed wiring board according to an aspect of the present disclosure is a flexible printed wiring board including an insulating base film and a conductive pattern stacked on one surface side of the base film. The flexible printed wiring board further includes one or more square-shaped connecting terminals stacked over the conductive pattern with solder in between on one edge side of the conductive pattern. The connecting terminal is made of metal and includes a bent portion with both ends bent opposite to the base film. The connecting terminal includes a plated layer on an outer surface side of the bent portion.

A method of manufacturing a flexible printed wiring board according to another aspect of the present disclosure is a method of manufacturing a flexible printed wiring board including an insulating base film and a conductive pattern stacked on one surface side of the base film. The method includes a connecting terminal preparation step of preparing a square-shaped connecting terminal, and a connecting terminal stacking step of stacking the connecting terminal prepared in the connecting terminal preparation step over the conductive pattern with solder in between on one edge side of the conductive pattern. The method includes, as the connecting terminal preparation step, a plated layer formation step of forming a plated layer on one surface of a metallic plate, a cutting step of cutting the metallic plate after the plated layer formation step into a plurality of square-shaped metallic pieces, and a bent portion formation step of bending both ends of each of the plurality of metallic pieces after the cutting step such that the plated layer is an outer surface. In the connecting terminal stacking step, the connecting terminal is stacked such that a bent portion of the connecting terminal is opposite to the base film.

### BRIEF DESCRIPTION OF DRAWINGS

FIG. 1 is a schematic lateral view of a flexible printed wiring board according to an embodiment of the present disclosure.

FIG. 2 is a schematic sectional view taken along the line A-A of FIG. 1.

FIG. 3 is a flow diagram schematically showing a method of manufacturing a flexible printed wiring board according to an embodiment of the present disclosure.

FIG. 4 is a flow diagram schematically showing a connecting terminal preparation step of FIG. 3.

FIG. 5 is a plan view of a battery wiring module 100.

### DETAILED DESCRIPTION

### Problem to be Solved by the Present Disclosure

The metallic connecting terminal described above is manufactured from a metallic plate larger in size than this connecting terminal by cutting (sheet metal processing). An end surface of the connecting terminal is first exposed to outside after the sheet metal processing, and can be subjected to plating. In conventional manufacture of a connecting terminal, accordingly, the end surface is plated after cutting. Thus, plating needs to be performed on metallic pieces after cutting, easily resulting in variations in melting quality and an increase in processing cost.

The present disclosure has been made in view of the above circumstances. An object of the present disclosure is to provide a flexible printed wiring board and a method of manufacturing a flexible printed wiring board that lead to improved adhesion between a connecting terminal and a conductive pattern with reduced variations in plating quality and a reduced processing cost of a connecting terminal.

### Advantageous Effect of the Present Disclosure

A flexible printed wiring board of the present disclosure and a method of manufacturing a flexible printed wiring board of the present disclosure lead to improved adhesion between a connecting terminal and a conductive pattern with reduced variations in plating cost and a reduced processing cost of the connecting terminal.

### Description of Embodiments

A flexible printed wiring board according to an aspect of the present disclosure is a flexible printed wiring board including an insulating base film and a conductive pattern stacked on one surface side of the base film. The flexible printed wiring board further includes one or more square-shaped connecting terminals stacked over the conductive pattern with solder in between on one edge side of the conductive pattern. The connecting terminal is made of metal and includes a bent portion with both ends bent opposite to the base film. The connecting terminal includes a plated layer on an outer surface side of the bent portion.

The flexible printed wiring board has the bent portion obtained by bending both ends of the square-shaped connecting terminal to the side opposite to the base film. The flexible printed wiring board, which is provided with the plated layer on the outer surface side of the bent portion, allows easy formation of a solder fillet, leading to improved adhesion between the connecting terminal and the conductive pattern. The outer surface of the bent portion is located on a surface of a metallic plate before cutting, which serves as the base material of the connecting terminal, and accordingly, the outer surface of the bent portion can also be plated before cutting of the metallic plate. The flexible printed wiring board can thus have reduced variations in plating quality and a reduced manufacturing cost of the connecting terminal.

A solder fillet may be formed between the bent portion and the conductive pattern. The formation of the solder fillet between the bent portion and the conductive pattern in this manner can increase the contact area between the connecting terminal and the conductive pattern to further improve adhesion, leading to reduced occurrence of cracks of the solder.

A bent angle of the bent portion is preferably not less than 1° and not greater than 180°. Setting the bent angle to be within the above-mentioned range allows formation of the solder fillet with a reduced increase in the area of the connecting terminal in plan view. “Bent angle” refers to an angle formed between the central axis of the bent portion and the central axis of the bottom.

A height of projection of the bent portion from a surface of the conductive pattern is preferably not less than 0.05 mm and not greater than 10 mm. Setting the height of projection to be within the above range allows formation of the solder fillet with a reduced increase in the height of the connecting terminal.

A method of manufacturing a flexible printed wiring board according to another aspect of the present disclosure is a method of manufacturing a flexible printed wiring board including an insulating base film and a conductive pattern stacked on one surface side of the base film. The method includes a connecting terminal preparation step of preparing a square-shaped connecting terminal, and a connecting terminal stacking step of stacking the connecting terminal prepared in the connecting terminal preparation step over the conductive pattern with solder in between on one edge side of the conductive pattern. The method includes, as the connecting terminal preparation step, a plated layer formation step of forming a plated layer on one surface of a metallic plate, a cutting step of cutting the metallic plate after the plated layer formation step into a plurality of square-shaped metallic pieces, and a bent portion formation step of bending both ends of each of the plurality of metallic pieces after the cutting step such that the plated layer is an outer surface. In the connecting terminal stacking step, the connecting terminal is stacked such that a bent portion of the connecting terminal is opposite to the base film.

In the method of manufacturing a flexible printed wiring board, the connecting terminal is obtained by forming the plated layer on the metallic plate, and then, cutting the metallic plate into a square shape. The use of the method of manufacturing a flexible printed wiring board can thus reduce variations in the plating quality and a manufacturing cost of the connecting terminal. In the method of manufacturing a flexible printed wiring board, the connecting terminal is formed by bending both ends of the cut metallic plate. Thus, in stacking of the connecting terminal over the conductive pattern with solder in between on one edge side of the conductive pattern, the solder fillet can be easily formed, leading to improved adhesion between the connecting terminal and the conductive pattern.

### Detailed Description of Embodiments of the Present Disclosure

Embodiments of a flexible printed wiring board and a method of manufacturing a flexible printed wiring board according to the present disclosure will be described below in detail with reference to the drawings.

[Flexible Printed Wiring Board]

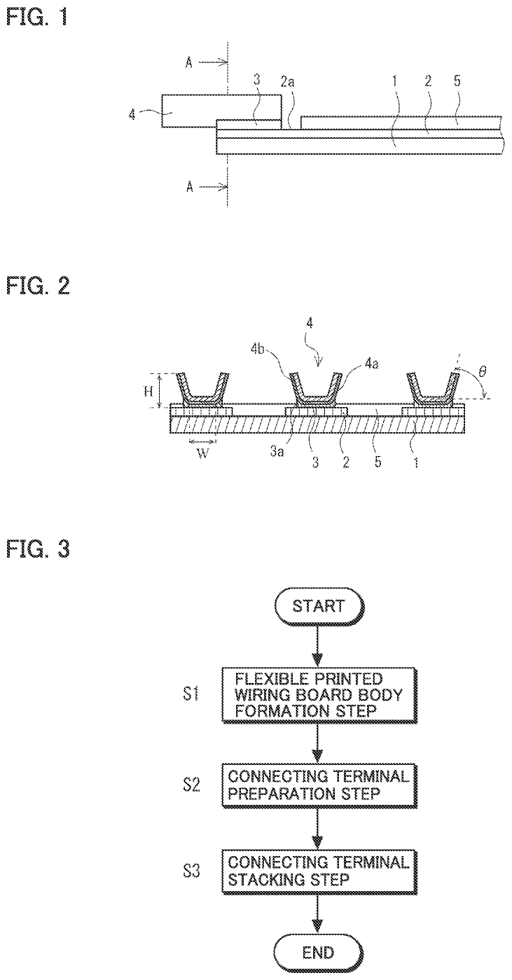

The flexible printed wiring board mainly includes an insulating base film 1, a conductive pattern 2, which is stacked on one surface side of base film 1, a plurality of square-shaped connecting terminals 4, which are stacked over conductive pattern 2 with solder 3 in between on one edge side of conductive pattern 2, and a coverlay 5 stacked on one surface of base film 1 or conductive pattern 2, as shown in FIGS. 1 and 2.

<Base Film>

Base film 1 is a member that supports conductive pattern 2, and is a structural member that guarantees the strength of the flexible printed wiring board. Base film 1 is also insulating and flexible.

The main component of base film 1 may be, for example, a soft material such as polyimide, a liquid crystal polymer represented by liquid crystal polyester, polyethylene terephthalate, polyethylene naphthalate, polyphenylene ether, or fluororesin, a hard material such as paper phenol, paper epoxy, glass composite, glass epoxy, or a glass substrate, or a rigid flexible material that is a composite of a soft material and a hard material. In particular, polyimide having an excellent heat resistance is preferred. Base film 1 may be porous, or may contain a filler, an additive, or the like. Herein, “main component” refers to a component having the highest content, which is, for example, a component having a content of not less than 50 percent by mass.

The thickness of base film 1 is not particularly limited, and the lower limit of the average thickness of base film 1 is preferably 5 μm, and more preferably 12 μm. The upper limit of the average thickness of base film 1 is preferably 500 μm, and more preferably 200 μm. If the average thickness of base film 1 is less than the above-mentioned lower limit, base film 1 may have an insufficient strength. If the average thickness of base film 1 is greater than the above-mentioned upper limit, the flexible printed wiring board may have insufficient flexibility.

<Conductive Pattern>

Conductive pattern 2 forms the structure, such as an electric wiring structure, a ground, or a shield.

The material for conductive pattern 2 is not particularly limited as long as it is a conductive material, and examples of the material include metals such as copper, aluminum, and nickel. Copper, which is relatively inexpensive and has a high conductivity, is generally used. The surface of conductive pattern 2 may be plated.

The lower limit of the average thickness of conductive pattern 2 is preferably 2 μm, and more preferably 5 μm. The upper limit of the average thickness of conductive pattern 2 is preferably 100 μm, and is more preferably 70 μm. If the average thickness of conductive pattern 2 is less than the above-mentioned lower limit, conductive pattern 2 may have insufficient conductivity. Contrastingly, if the average thickness of conductive pattern 2 is greater than the above-mentioned upper limit, the flexible printed wiring board may have an unnecessarily large thickness.

The flexible printed wiring board includes a terminal connection region 2a on one edge side of conductive pattern 2. Terminal connection region 2a is a region for connecting any other electronic device to the flexible printed wiring board with connecting terminal 4, described below, in between. In terminal connection region 2a, a coverlay 5, described below, is removed.

The shape of terminal connection region 2a is not particularly limited as long as terminal connection region 2a can be electrically connected to an individual connecting terminal 4, and it can be a square shape, for example. The size of terminal connection region 2a is determined in accordance with the size of connecting terminal 4, and connection region 2a can have, for example, an average width of not less than 0.5 mm and not greater than 3 mm and an average length of not less than 3 mm and not greater than 50 mm.

<Connecting Terminal>

Connecting terminal 4 is a part for connecting the flexible printed wiring board to any other electronic device or the like. Connecting terminal 4 is stacked over terminal connection region 2a located on one edge side of conductive pattern 2 with solder 3 in between, as described above. Connecting terminal 4 includes a bent portion 4a with both ends bent opposite to base film 1. With bent portion 4a, connecting terminal 4 is formed to be U-shaped in cross-section.

Connecting terminal 4 is made of a metal. Examples of the metal include soft copper, brass, phosphor bronze, and aluminum.

Connecting terminal 4 includes a plated layer 4b entirely on the outer surface side of connecting terminal 4 which includes the outer surface of bent portion 4a. Connecting terminal 4 includes no plated layer on its end surface. Examples of a plating of plated layer 4b on the outer surface side of bent portion 4a include a Sn plating, a Ni plating, and a Au plating. In particular, the Ni plating is preferable because it is inexpensive, has an excellent anticorrosive property, and allows easy formation of a solder fillet 3a, which will be described below. The thickness of plated layer 4b is not particularly limited and may be, for example, not less than 0.01 μm and not greater than 100 μm.

The lower limit of the average thickness of connecting terminal 4 (the overall average thickness including the plated layer) is preferably 0.05 mm, and more preferably 0.1 mm. The upper limit of the average thickness of connecting terminal 4 is preferably 5.0 mm, and more preferably 1.0 mm. If the average thickness of connecting terminal 4 is less than the above-mentioned lower limit, connecting terminal 4 may have an insufficient strength. Contrastingly, if the average thickness of connecting terminal 4 is greater than the above-mentioned upper limit, it may be difficult to bend both ends of connecting terminal 4 due to an unnecessarily large thickness of connecting terminal 4, or it may be difficult to handle the flexible printed wiring board due to the weight of connecting terminal 4.

The average length of connecting terminal 4 and the average width of the bottom of connecting terminal 4 are determined appropriately in accordance with the terminal shape of the electronic device to be connected or the like, and for example, the average length can be not less than 3 mm and not greater than 50 mm, and the average width can be not less than 0.5 mm and not greater than 3 mm. “Bottom” of connecting terminal 4 refers to a portion (W of FIG. 2) of the portion bonded to conductive pattern 2 by solder 3 except for the bent portions of U-shaped connecting terminal 4.

The lower limit of a height of projection (H of FIG. 2) of bent portion 4a from the surface of conductive pattern 2 is preferably 0.05 mm, more preferably 0.5 mm, and particularly preferably 1 mm. In contrast, the upper limit of the height of projection is preferably 10 mm, more preferably 3 mm, and particularly preferably 2 mm. If the height of projection is less than the above-mentioned lower limit, it may be difficult to bend both ends of connecting terminal 4. Contrastingly, if the height of projection is greater than the upper limit, connecting terminal 4 may have an unnecessarily large height, making it difficult to handle the flexible printed wiring board.

The lower limit of a bent angle (θ of FIG. 2) of bent portion 4a is preferably 1°, more preferably 45°, and particularly preferably 60°. The bent angle is preferably less than 180°, more preferably less than 90°, and particularly less than 80°. If the bent angle is less than the above-mentioned lower limit, connecting terminal 4 may become unnecessarily larger widthwise, making it difficult to handle the flexible printed wiring board. Contrastingly, if the bent angle is not less than the above-mentioned upper limit, it may be difficult to form solder fillet 3a.

The lower limit of the ratio of the radius of curvature of the bent portion of U-shaped connecting terminal 4 to the average thickness of connecting terminal 4 is preferably 1.5 times, and more preferably 1.8 times. The upper limit of the ratio of the radius of curvature is preferably 3 times, and more preferably 2.5 times. If the ratio of the radius of curvature is less than the above-mentioned lower limit, connecting terminal 4 may be broken easily at the bent portion. Contrastingly, if the ratio of the radius of curvature is greater than the above-mentioned upper limit, connecting terminal 4 may become unnecessarily larger widthwise, making it difficult to handle the flexible printed wiring board.

The lower limit of the radius of curvature of the bent portion of U-shaped connecting terminal 4 is preferably 0.1 mm, and more preferably 0.2 mm. The upper limit of the radius of curvature is preferably 1 mm, and more preferably 0.5 mm. If the radius of curvature is less than the above-mentioned lower limit, connecting terminal 4 may be broken easily at the bent portion. Contrastingly, if the radius of curvature is greater than the above-mentioned upper limit, connecting terminal 4 may become unnecessarily larger widthwise, making it difficult to handle the flexible printed wiring board.

Connecting terminal 4 is stacked over terminal connection region 2a of conductive pattern 2 with solder 3 in between, as described above. The type of solder 3 is not particularly limited, and for example, well-known lead-free solder or the like can be used.

Solder 3 is stacked mainly between the bottom of connecting terminal 4 and conductive pattern 2. The lower limit of the average thickness of solder 3 at this stacked portion (the average interval between the bottom of connecting terminal 4 and conductive pattern 2) is preferably 10 μm, and more preferably 100 μm. The upper limit of the average thickness of solder 3 is preferably 300 μm, and more preferably 200 μm. If the average thickness of solder 3 is less than the above-mentioned lower limit, the bonding strength between connecting terminal 4 and conductive pattern 2 may be insufficient. Contrastingly, if the average thickness of solder 3 is greater than the above-mentioned upper limit, the amount of solder 3 may increase unnecessarily, leading to a decrease in manufacturing efficiency or an increase in manufacturing cost.

As shown in FIG. 2, solder 3 may also be stacked between the lower end (bent portion) of bent portion 4a and conductive pattern 2 to form solder fillet 3a. The formation of solder fillet 3a between bent portion 4a and conductive pattern 2 in this manner can increase the contact area between connecting terminal 4 and conductive pattern 2 to improve adhesion, leading to reduced occurrence of cracks of solder 3 or the like.

The height of solder fillet 3a to be formed depends on the viscosity of solder 3 used, the radius of curvature of the bent portion at the lower end of bent portion 4a, or the like. Preferably, solder fillet 3a is flush with the top surface of the bottom of connecting terminal 4 or is located above the top surface of the bottom of connecting terminal 4.

<Coverlay>

Coverlay 5 protects conductive pattern 2 from an external force, moisture, or the like. Coverlay 5 includes a cover film and an adhesion layer. Coverlay 5 is obtained by stacking a cover film over a surface of conductive pattern 2 opposite to base film 1 with the adhesion layer in between.

(Cover Film)

The material of the cover film is not particularly limited and may be, for example, a material similar to the resin of base film 1.

The lower limit of the average thickness of the cover film is preferably 5 μm, and more preferably 10 μm. The upper limit of the average thickness of the cover film is preferably 50 μm, and more preferably 30 μm. If the average thickness of the cover film is less than the above-mentioned lower limit, insulation may be insufficient. Contrastingly, if the average thickness of the cover film is greater than the above-mentioned upper limit, the flexibility of the flexible printed wiring board may be impaired.

(Adhesion Layer)

The adhesion layer fixes the cover film to conductive pattern 2 and base film 1. The material of the adhesion layer is not particularly limited as long as the cover film can be fixed to conductive pattern 2 and base film 1, and is preferably a material having excellent flexibility or an excellent heat resistance. Examples of the material include a polyimide, a polyamide, an epoxy, a butyral, and an acrylic. In terms of heat resistance, a thermosetting resin is preferred.

The average thickness of the adhesion layer of coverlay 5 is not particularly limited. The lower limit of the average thickness of the adhesion layer is, for example, preferably 5 μm, and more preferably 10 μm. The upper limit of the average thickness of the adhesion layer is, for example, preferably 100 μm, and more preferably 80 μm. If the average thickness of the adhesion layer is less than the above-mentioned lower limit, adhesion may be insufficient. Contrastingly, if the average thickness of the adhesion layer is greater than the above-mentioned upper limit, the flexibility of the flexible printed wiring board may be impaired.

[Method of Manufacturing Flexible Printed Wiring Board]

A method of manufacturing the flexible printed wiring board mainly includes a flexible printed wiring board formation step S1, a connecting terminal preparation step S2, and a connecting terminal stacking step S3, as shown in FIG. 3.

<Flexible Printed Wiring Board Formation Step>

In flexible printed wiring board formation step S1, a flexible printed wiring board body is formed that includes insulating base film 1, conductive pattern 2 stacked on one surface side of base film 1, and coverlay 5 stacked on one surface of base film 1 or conductive pattern 2. Specifically, this step is performed in the following procedure.

First, a conductor layer is formed on one surface of base film 1.

The conductor layer can be formed, for example, by bonding a foil-shaped conductor with an adhesive, or by a well-known deposition technique. Examples of the conductor include copper, silver, gold, and nickel. The adhesive is not particularly limited as long as the conductor can be bonded to base film 1, and may be various types of adhesives. Examples of the deposition technique include vapor deposition and plating. The conductor layer is preferably formed by bonding a copper foil to base film 1 with a polyimide adhesive.

Subsequently, the conductor layer is patterned to form conductive pattern 2.

The conductor layer can be patterned by a known method, for example, photoetching. Photoetching is performed by forming a resist film having a prescribed pattern on one surface of the conductor layer, and then, treating the conductor layer exposed from the resist film with an etchant to remove the resist film.

Lastly, coverlay 5 is stacked to cover conductive pattern 2 except for terminal connection region 2a on one edge side of conductive pattern 2. Specifically, an adhesive layer is stacked on the surface of base film 1 on which conductive pattern 2 is formed, and the cover film is stacked on the adhesive layer. Alternatively, an adhesive layer may be stacked on a cover film in advance, and the cover film may be bonded to conductive pattern 2 with the surface of the cover film, on which the adhesive layer is stacked, facing conductive pattern 2.

Bonding of the cover film with an adhesive can be generally performed by thermal compression bonding. The temperature and pressure in thermal compression bonding may be determined appropriately in accordance with the type, composition, or the like of the adhesive used.

Flexible printed wiring board formation step S1 may be performed after connecting terminal preparation step S2 described below. In other words, flexible printed wiring board formation step S1 and connecting terminal preparation step S2 can be performed in any order.

<Connecting Terminal Preparation Step>

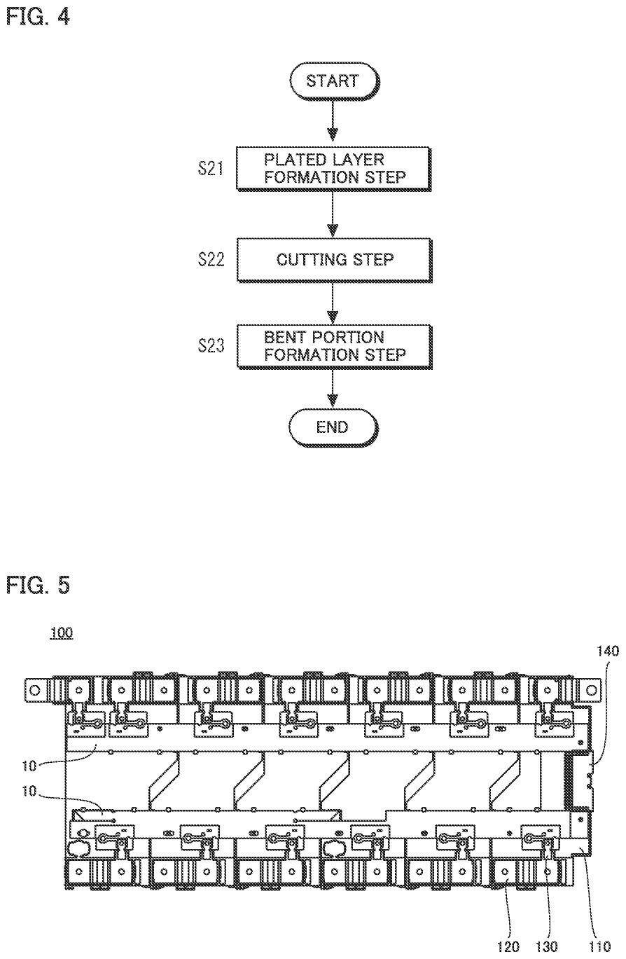

In connecting terminal preparation step S2, square-shaped connecting terminal 4 is prepared. The method of manufacturing a flexible printed wiring board includes a plated layer formation step S21, a cutting step S22, and a bent portion formation step S23 as connecting terminal preparation step S2, as shown in FIG. 4.

(Plated Layer Formation Step)

In plated layer formation step S21, a plated layer is formed on one surface of a metallic plate.

The metallic plate used in plated layer formation step S21 is a metallic plate of the same type as that of the metal of connecting terminal 4. The metallic plate has such a size that allows a plurality of connecting terminals 4 to be cut out in cutting step S22 described below.

The method of forming a plated layer is not particularly limited, and for example, may be well-known electroplating or electroless plating.

(Cutting Step)

In cutting step S22, the metallic plate after plated layer formation step S21 is cut into a plurality of square-shaped metallic pieces.

The shape and size of the cut metallic piece are equal to the shape and size of a desired connecting terminal 4 with both ends of bent portion 4a being extended on the same plane as that of the bottom. In other words, the shape and size of the cut metallic piece are a shape and a size that allow formation of connecting terminal 4 only by bending the metallic piece.

The method of cutting the metallic plate is not particularly limited, and for example, a well-known metal cutting machine can be used.

(Bent Portion Formation Step)

In bent portion formation step S23, both ends of the metallic piece after cutting step S22 are bent to provide a U-shaped cross section such that the plated layer is the outer surface.

The method of bending the metallic piece is not particularly limited and may be, for example, die machining.

Thus, connecting terminal 4 can be obtained that includes bent portion 4a with both ends bent and includes plated layer 4b on the outer surface side of bent portion 4a. The number of connecting terminals 4 prepared is not less than the number of connecting terminals stacked on at least one flexible printed wiring board body. When there are surplus connecting terminals 4, the surplus connecting terminals 4 may be stacked on another flexible printed wiring board body.

<Connecting Terminal Stacking Step>

In connecting terminal stacking step S3, connecting terminal 4 prepared in connecting terminal preparation step S2 is stacked over conductive pattern 2 with solder 3 in between on one edge side of conductive pattern 2. In connecting terminal stacking step S3, connecting terminal 4 is stacked such that bent portion 4a of connecting terminal 4 is opposite to base film 1.

Connecting terminal 4 can be stacked using solder 3, for example, in the following procedure. First, solder 3 is provided in terminal connection region 2a of conductive pattern 2. Connecting terminal 4 is placed on solder 3 such that bent portion 4a is opposite to base film 1, that is, the bottom of the U-shape is in contact with solder 3. Solder 3 is melted by reflow in this state, so that connecting terminal 4 can be soldered to conductive pattern 2.

At this time, as the region in which solder 3 is provided and an amount of solder 3 are adjusted, or connecting terminal 4 is pressed toward base film 1 during reflow, solder 3 can also be stacked between the lower end (bent portion) of bent portion 4a and conductive pattern 2, thus forming solder fillet 3a.

When the flexible printed wiring board body includes a plurality of terminal connection regions 2a, connecting terminal 4 is stacked on each terminal connection region 2a. In this case, connecting terminals 4 can be stacked one by oy by repeating connecting terminal stacking step S3. In terms of manufacturing efficiency, preferably, a plurality of connecting terminals 4 are placed at a time and soldered by one reflow.

### Advantageous Effects

In the method of manufacturing a flexible printed wiring board, connecting terminal 4 is obtained by forming a plated layer on a metallic plate, and then, cutting the metallic plate is cut into a square shape. The use of the method of manufacturing a flexible printed wiring board can thus reduce variations in the plating quality and a processing cost of connecting terminal 4. In the method of manufacturing a flexible printed wiring board, since the both ends of the cut metallic plate are bent to form connecting terminal 4, solder fillet 3a can be easily formed when connecting terminal 4 is stacked over conductive pattern 2 with solder 3 in between on one edge side of conductive pattern 2, leading to improved adhesion between connecting terminal 4 and conductive pattern 2.

The flexible printed wiring board includes bent portion 4a obtained by bending both ends of square-shaped connecting terminal 4 opposite to base film 1. Thus, the outer surface of bent portion 4a can also be plated before cutting the metallic plate which is the base material of connecting terminal 4, leading to reduced variations in plating quality and a processing cost of connecting terminal 4, as well as improved adhesion between connecting terminal 4 and conductive pattern 2.

### Other Embodiments

It should be understood that the embodiments disclosed herein are illustrative and non-restrictive in all respects. The scope of the present invention is not limited to the configurations of the above-described embodiments, but is indicated by the claims, and is intended to include all modifications within the meaning and range equivalent to the claims.

Although the above embodiments have described a flexible printed wiring board including a plurality of connecting terminals, one connecting terminal may be included.

Although the above embodiments have described the case where the plated layer is provided only on the outer surface side of the bent portion of the connecting terminal, the present disclosure also covers the case where the plated layers are provided on both surfaces of the connecting terminal.

Although the above embodiments have described the case where the plated layer is entirely provided on the outer surface side of the bent portion of the connecting terminal, the plated layer may be disposed only at a part on the outer surface side of the bent portion of the connecting terminal, for example, at a position at which the bent portion is in contact with the solder.

Although the above embodiments have described the flexible printed wiring board including the coverlay, the coverlay is not an essential constituent element and can be omitted. Alternatively, one surface of a base film or a conductive pattern may be covered with an insulating layer of any other configuration.

(Battery Wiring Module)

A battery wiring module (referred to as “battery wiring module 100”) according to one aspect of the present disclosure will be described below. FIG. 5 is a plan view of battery wiring module 100. As shown in FIG. 5, battery wiring module 100 includes a flexible printed wiring board 10, an insulating protector 110, a bus bar 120, a relay member 130, and a connector 140. Flexible printed wiring board 10 is the flexible printed wiring board described above.

Insulating protector 110 is a plate-shaped member. Insulating protector 110 is formed of an insulating material. The insulating material is, for example, an insulating synthetic resin. Flexible printed wiring board 10 is placed on the upper surface of insulating protector 110.

Bus bar 120 is a plate-shaped member formed of a conductive material. The conductive material is, for example, a metallic material. The metallic member is, for example, copper, a copper alloy, aluminum, an aluminum alloy, stainless steel (SUS), or the like. Bus bar 120 is electrically connected to a power storage element (not shown). The power storage element is, for example, a secondary battery. Bus bar 120 allows series or parallel connection of any number of power storage elements.

Relay member 130 is a plate-shaped member formed of a conductive material.

The conductive material is, for example, a metallic material. The metallic material is, for example, copper, a copper alloy, aluminum, an aluminum alloy, stainless steel (SUS), nickel, a nickel alloy, or the like. Relay member 130 electrically connects an extra length adsorbing portion of flexible printed wiring board 10 to bus bar 120. Battery wiring module 100 may include no relay member 130. In this case, bus bar 120 is electrically connected to the extra length adsorbing portion of flexible printed wiring board 10 without relay member 130. Battery wiring module 100 is electrically connected to an external device or the like by connector 140.

As described above, the flexible printed wiring board of the present disclosure is adaptable to battery wiring module 100 attached to a power storage module including a power storage element.

### INDUSTRIAL APPLICABILITY

As described above, a flexible printed wiring board of the present disclosure and a method of manufacturing a flexible printed wiring board of the present disclosure lead to improved adhesion between a connecting terminal and a conductive pattern with reduced variations in plating quality and a reduced processing cost of a connecting terminal.

### REFERENCE SIGNS LIST

1 base film; 2 conductive pattern; 2a terminal connection region; 3 solder; 3a solder fillet; 4 connecting terminal; 4a bent portion; 4b plated layer; 5 coverlay; 100 battery wiring module; 110 insulating protector; 120 bus bar; 130 relay member; 140 connector; 10 flexible printed wiring board.

1. A flexible printed wiring board comprising an insulating base film and a conductive pattern stacked on one surface side of the base film,
the flexible printed wiring board further comprising one or more square-shaped connecting terminals stacked over the conductive pattern with solder in between on one edge side of the conductive pattern,
the connecting terminal being made of metal and including a bent portion with both ends bent opposite to the base film,
the connecting terminal including a plated layer on an outer surface side of the bent portion.

2. The flexible printed wiring board according to claim 1, wherein a solder fillet is formed between the bent portion and the conductive pattern.

3. The flexible printed wiring board according to claim 1, wherein a bent angle of the bent portion is not less than 1° and not greater than 180°.

4. The flexible printed wiring board according to claim 1, wherein a height of projection of the bent portion from a surface of the conductive pattern is not less than 0.05 mm and not greater than 10 mm.

5. A battery wiring module comprising a flexible printed wiring board according to claim 1,
the battery wiring module being attached to a battery module mounted on a vehicle.

6. A method of manufacturing a flexible printed wiring board including an insulating base film and a conductive pattern stacked on one surface side of the base film, the method comprising:
a connecting terminal preparation step of preparing a square-shaped connecting terminal; and
a connecting terminal stacking step of stacking the connecting terminal prepared in the connecting terminal preparation step over the conductive pattern with solder in between on one edge side of the conductive pattern;
the method comprising as the connecting terminal preparation step,
a plated layer formation step of forming a plated layer on one surface of a metallic plate,
a cutting step of cutting the metallic plate after the plated layer formation step into a plurality of square-shaped metallic pieces, and
a bent portion formation step of bending both ends of each of the plurality of metallic pieces after the cutting step such that the plated layer is an outer surface,
in the connecting terminal stacking step, the connecting terminal being stacked such that a bent portion of the connecting terminal is opposite to the base film.
